(19) United States
(12) Patent Application Publication
(10) Pub. No.: US 2007/0111505 A1
(43) Pub. Date: May 17, 2007

(54) Method of manufacturing a semiconductor device

(75) Inventors: Michio Oryoji, Kawasaki (JP); Kunihiko Nagase, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/356,042

(22) Filed: Feb. 17, 2006

(30) Foreign Application Priority Data
Nov. 11, 2005 (JP) 2005-327878

(51) Int. Cl. H01L 21/4763

(52) U.S. Cl. 438/618

(57) ABSTRACT

A semiconductor device manufacturing method forming an interconnection structure by a dual damascene process is disclosed that includes the steps of forming first and second interlayer insulating films successively over an interconnection layer, at least one of which includes a low dielectric constant material; forming a via hole through the first and second interlayer insulating films; filling the via hole with a burying material including an acid generator; causing an acid substance to be generated in the burying material; forming a chemically amplified resist film covering the second interlayer insulating film and the burying material; forming the pattern of an interconnection trench in the area including the via hole over the chemically amplified resist film; forming the interconnection trench by etching the second interlayer insulating film using the chemically amplified resist film as a mask; and filling the via hole and the interconnection trench with a conductive material.

### CROSS-REFERENCE TO RELATED APPLICATION

The present application is based on Japanese Priority Patent Application No. 2005-327878, filed on Nov. 11, 2005, the entire contents of which are hereby incorporated by reference.

### BACKGROUND OF THE INVENTION

1. Field of the Invention

The present invention relates generally to methods of manufacturing a semiconductor device, and more particularly to a method of manufacturing a semiconductor device which method forms an interconnection structure by a dual damascene process.

2. Description of the Related Art

In recent years, as semiconductor devices have been provided with more functions and become more sophisticated, there has been pursued high integration in which a significant increase in the number of transistors mounted on a single chip and a reduction in chip size progress simultaneously. With this high integration of semiconductor devices, it is required to increase the number of interconnections with a reduced chip size, so that interconnection structures with higher density have been pursued.

As interconnection structures are provided with higher density, interconnection delay due to a so-called “RC product,” the product of an increase in interconnection capacitance C because of reduction in the distance between interconnections and an increase in interconnection resistance R because of reduction in interconnection width, increases.

In order to solve this problem and to reduce interconnection capacitance, a film of low dielectric constant material, a so-called “low-k” film, has been used for an interlayer insulating film. The low-k film has a lower dielectric constant than a silicon oxide film (SiO₂, a relative dielectric constant of approximately 4.3), conventionally used as an interlayer insulating film. As low-k films, inorganic insulating films of SiOC or porous silica and polyimide-based or Teflon (registered trademark)-based organic insulating films have been proposed.

Further, in order to reduce interconnection delay and to reduce interconnection resistance R, interconnection structures formed by the dual damascene process using Cu interconnections have been employed. In the dual damascene process, a via that is a vertical interconnection and the interconnection of an interconnection layer are formed at the same time. According to the dual damascene process, a via hole and an interconnection trench are formed and, thereafter, filled with Cu. The surface of Cu is flattened by chemical mechanical polishing (CMP). As one dual damascene method, a so-called “via-first” method, first forming a via hole and then forming an interconnection trench, is employed.

FIGS. 1A and 1B are diagrams showing a conventional interconnection process according to the via-first method. Referring to FIG. 1A, according to the via-first method, a via hole 106a is formed in interlayer insulating films 103 and 104 stacked on an interconnection layer 101, and thereafter, the via hole 106a is filled with a burying material 108 formed of resin. A variation in the density of the via holes 106a results from the design of a semiconductor device. The surface of a resist film applied on the interlayer insulating film 104 in a later process is less flat in the area in which the via holes 106a are formed with higher density than in the area in which the via holes 106a are formed with lower density. This makes it difficult to perform focusing at the time of exposure of a resist film 110 by photolithography. Therefore, the via hole 106a is filled with the burying material 108 before applying the resist film 110, thereby improving the flatness of the resist film 110.

In this respect, reference may be made to Japanese Laid-Open Patent Application No. 2003-229481.

The low-k film used for each of the interlayer insulating films 103 and 104 has not only a lower relative dielectric constant but also a lower density than the silicon oxide film. Accordingly, the low-k film has the property of being likely to absorb a process gas and an etching gas used in its formation, and retaining an extremely greater amount of gas than the silicon oxide film.

Referring to FIG. 1A, in an exposure process, the resist film 110, formed of a chemically amplified resist material, is exposed in the pattern of an interconnection trench, so that a latent image 110a is formed. Then, as shown in FIG. 1B, the area exposed by a development process (the area of the latent image 110a) is dissolved using a development agent, so that an opening part 110b is formed. However, a resist film 110c that should have been dissolved may remain in the area so as to cause poor resolution. This phenomenon is referred to as “resist poisoning,” or simply, “poisoning.” The occurrence of resist poisoning prevents a desired interconnection structure from being formed and causes disconnection or poor conductance of an interconnection, thus causing the problem of a decrease in the yield and the reliability of semiconductor devices.

### SUMMARY OF THE INVENTION

Accordingly, it is a general object of the present invention to provide a method of manufacturing a semiconductor device in which the above-described disadvantage is eliminated.

A more specific object of the present invention is to provide a method of manufacturing a semiconductor device which method is capable of preventing resist poisoning and forming a fine interconnection structure.

The above objects of the present invention are achieved by a method of manufacturing a semiconductor device, the method forming an interconnection structure by a dual damascene process, the method including the steps of: (a) forming a first interlayer insulating film and a second interlayer insulating film successively over an interconnection layer, at least one of the first interlayer insulating film and the second interlayer insulating film being formed of a low dielectric constant material; (b) forming a via hole through the first interlayer insulating film and the second interlayer insulating film; (c) filling the via hole with a burying material formed of a material including an acid generator; (d) causing an acid substance to be generated in the burying material; (e) forming a chemically amplified resist film covering the second interlayer insulating film and the burying material; (f) forming a pattern of an interconnection trench in an area including the via hole over the chemically amplified resist film; (g) forming the interconnection trench by etching the second interlayer insulating film using the chemically amplified resist film as a mask; and (h) filling the via hole and the interconnection trench with a conductive material.

The above objects of the present invention are also achieved by a method of manufacturing a semiconductor device, the method forming an interconnection structure by a dual damascene process, the method including the steps of: (a) forming a cap layer, a first interlayer insulating film of a low dielectric constant material, an etching stopper layer, a second interlayer insulating film of a low dielectric constant material, and a hard mask layer successively over an interconnection layer; (b) forming a via hole exposing a surface of the cap layer by etching the first interlayer insulating film, the etching stopper layer, the second interlayer insulating film, and the hard mask layer; (c) forming a burying material of a material including an acid generator so that the via hole is filled and a surface of the hard mask layer is covered with the burying material; (d) causing an acid substance to be generated in the burying material by irradiating a substantially entire surface of the burying material with energy lines; (e) heating the burying material, the first interlayer insulating film, and the second interlayer insulating film; (f) forming a chemically amplified resist film covering the hard mask layer and the burying material; (g) forming a pattern of an interconnection trench in an area including the via hole over the chemically amplified resist film; (h) forming the interconnection trench by etching the second interlayer insulating film using the chemically amplified resist film as a mask; and (i) filling the via hole and the interconnection trench with a conductive material.

According to one aspect of the present invention, by using a material including an acid generator generating an acid substance as a burying material with which a via hole is filled, it is possible to neutralize a basic substance occluded in an interlayer insulating film of a low dielectric constant material, and to prevent the basic substance from acting on an acid substance generated by exposure of a chemically amplified resist film. As a result, it is possible to prevent occurrence of resist poisoning and thus form a fine interconnection structure.

That is, according to one aspect of the present invention, by using a material generating an acid substance as a burying material to fill in a via hole, it is possible to provide a semiconductor device manufacturing method capable of forming a fine interconnection structure by preventing occurrence of resist poisoning.

### BRIEF DESCRIPTION OF THE DRAWINGS

Other objects, features and advantages of the present invention will become more apparent from the following detailed description when read in conjunction with the accompanying drawings, in which:

FIGS. 1A and 1B are diagrams showing a conventional interconnection process according to a via-first method;

FIGS. 2A through 2H are diagrams showing a process of manufacturing a semiconductor device according to a first embodiment of the present invention;

FIGS. 3A and 3B show the photographs of the resist films of an example according to the first embodiment of the present invention and a comparative example, respectively, after a development process; and

FIG. 4 is a diagram showing part of a process of manufacturing a semiconductor device according to a second embodiment of the present invention.

### DETAILED DESCRIPTION OF THE PREFERRED EMBODIMENTS

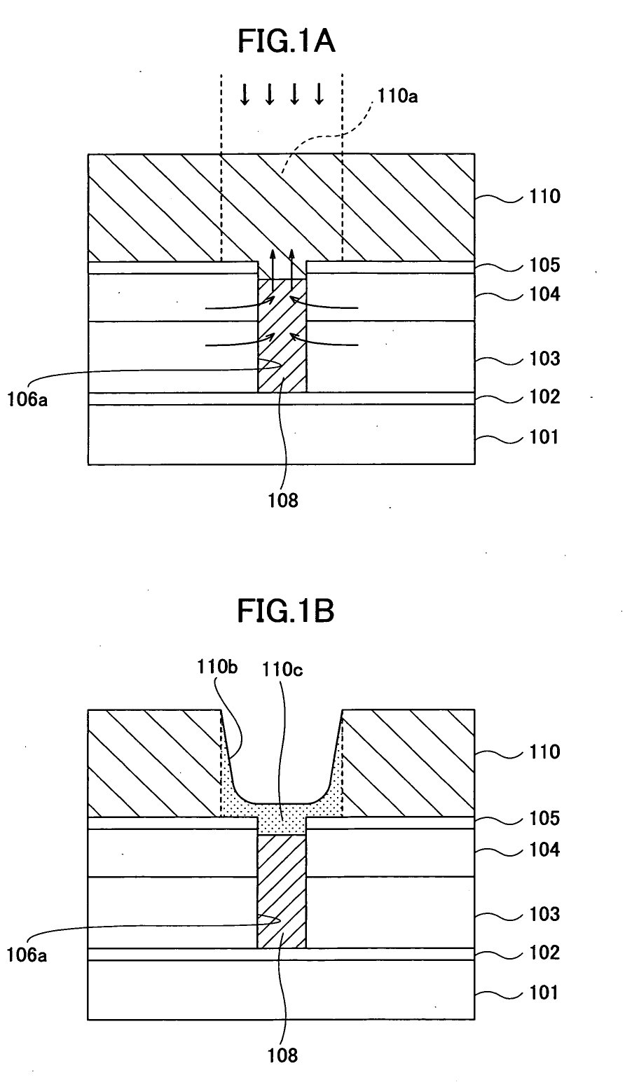

The inventors of the present invention have analyzed the cause of poisoning and made the present invention as follows. That is, for example, in a resist film formed of a positive chemically amplified resist material, an acid substance is generated in the area illuminated with exposure light by an acid generator included in the resist material. Next, when the resist film is heated (for example, prebaked), the acid substance decomposes a dissolution inhibitor so as to convert the resist film into a structure soluble in alkaline development liquid. At the time of this exposure or heating, as shown in FIG. 1A, a basic substance occluded in the interlayer insulating films 103 and 104, such as a compound having an amino group, flows into the burying material 108 of the via hole 106a. The low-k material is sandwiched between a cap layer 102 and an etching stopper layer 105 provided under and on the low-k material, respectively, each having a denser structure than the low-k material. Accordingly, the basic substance is diffused and penetrates into the burying material 108 formed of a resin material, which resin material is relatively easy to penetrate, and further reaches the resist film 110 on the burying material 108. Then, the acid substance in the resist film 110 is neutralized by the action of the basic substance, thus causing a shortage of the acid substance acting on the dissolution inhibitor. As a result, the function of the dissolution inhibitor of the resist film 110 cannot be stopped satisfactorily, so that after the development process, the resist film 110c remains in the area that should have been dissolved as shown in FIG. 1B.

The inventors of the present invention have found that it is possible to prevent resist poisoning by employing a burying material that generates a substance to neutralize the basic substance so as to prevent the basic substance from reaching the resist film 110.

In the specification of the present application, a low dielectric constant material (also referred to as “low-k material”) refers to a material having a lower dielectric constant than a silicon oxide film (SiO₂, with a relative dielectric constant of approximately 4.3). Further, a low-k film refers to a film formed of a low-k material.

A description is given below, with reference to the accompanying drawings, of embodiments of the present invention.

### First Embodiment

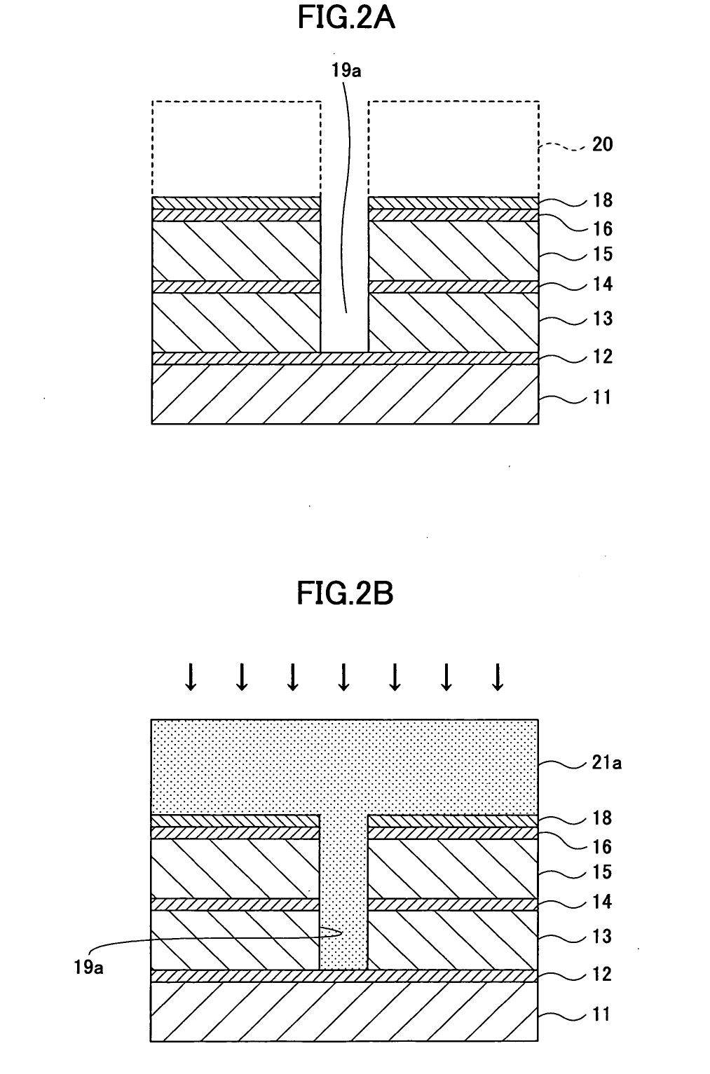

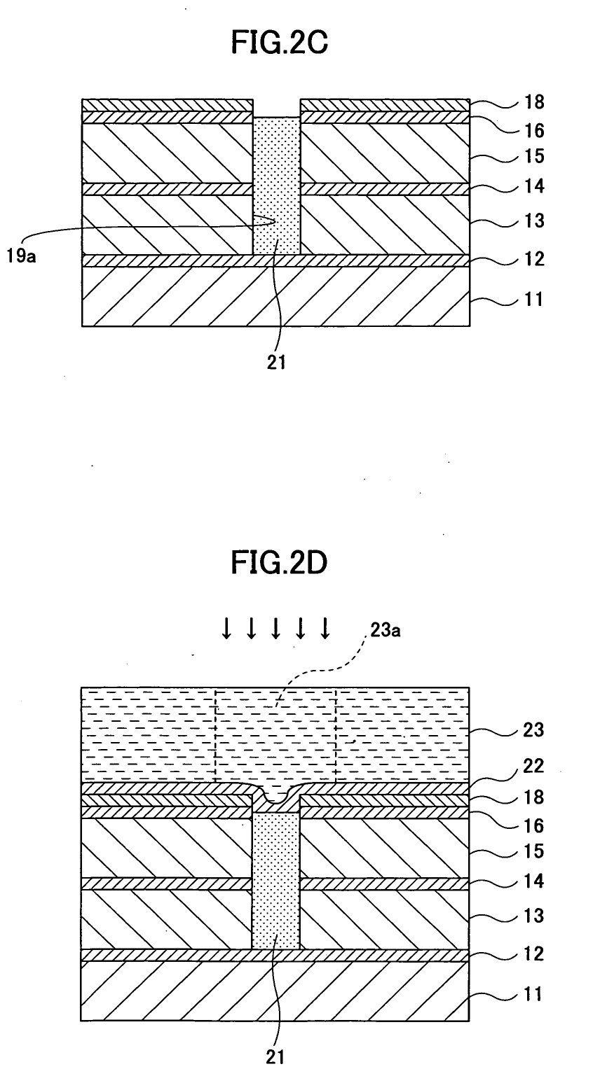

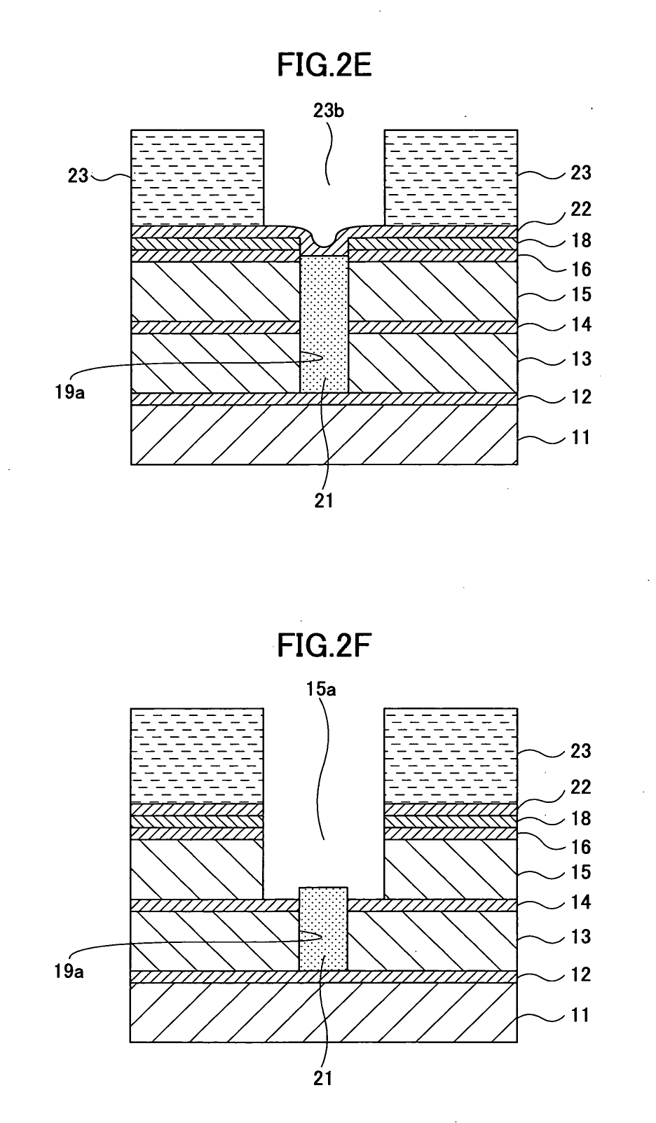

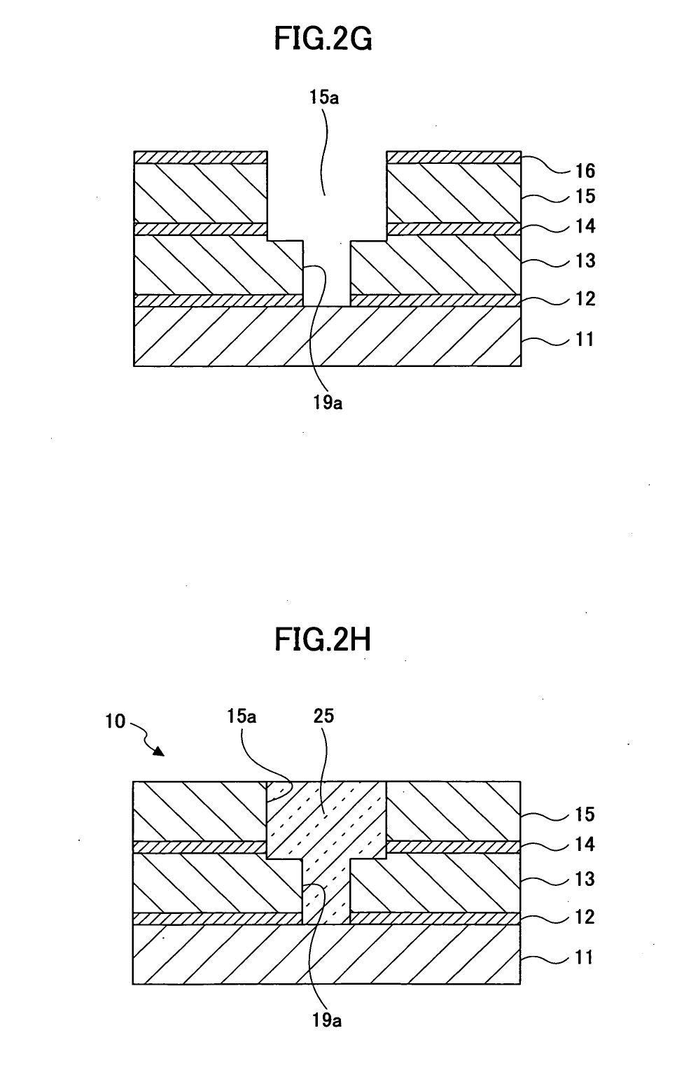

FIGS. 2A through 2H are diagrams showing a process of manufacturing a semiconductor device according to a first embodiment of the present invention.

First, in the process of FIG. 2A, a cap layer 12, a first interlayer insulating film 13, an etching stopper layer 14, a second interlayer insulating film 15, a hard mask layer 16, and a hard mask layer 18 are successively formed on an interconnection layer 11. Specifically, a SiC film (for example, 70 nm in thickness) is used as the cap layer 12. SiOC films, which are low-k films (for example, 550 nm and 370 nm in thickness), are used as the first interlayer insulating film 13 and the second interlayer insulating film 15, respectively. A SiC film (for example, 30 nm in thickness) is used as the etching stopper layer 14. A tetraethylorthosilicate (TEOS) film (for example, 30 nm in thickness) is used as the hard mask layer 16. A SiN film (for example, 50 nm in thickness) is used as the hard mask layer 18. Each of these layers 12 through 16 and 18 is formed using chemical vapor deposition (CVD) or sputtering.

As the first interlayer insulating film 13 and the second interlayer insulating film 15, in addition to a SiOC film, also employable are such low-k films as: inorganic insulting films such as SiOF and BSG (SiO₂—B₂O₃) films with relative dielectric constants of 3.5-3.7; porous silica such as Nano Clustering Silica (NCS, the name of a Catalysts & Chemicals Industries Co., Ltd. product) and Porous SiLK (registered trademark) Y (the name of a Dow Chemical Company product) with a relative dielectric constant of 2.4; and organic siloxane such as porous Black Diamond (the name of an Applied Materials Inc. product), CORAL (registered trademark, a Novellus Systems Inc. product) with a relative dielectric constant of 3.2, and HOSP (registered trademark, a Honeywell Electronic Materials product) with a relative dielectric constant of 2.5.

In the process of FIG. 2A, a resist film 20 is further formed on the surface of the hard mask layer 18, and an opening part is formed in the position where a via hole 19a is to be formed. Further, the via hole 19a is formed by dry etching using, for example, CF₄ gas and O₂ gas with the resist film 20 serving as a mask. The via hole 19a is an opening part that penetrates the hard mask layer 18, the hard mask layer 16, the second interlayer insulating film 15, the etching stopper layer 14, and the first interlayer insulating film 13 so as to expose the surface of the cap layer 12. Further, the resist film 20 is removed.

Next, in the process of FIG. 2B, a burying material 21a to cover the structure of FIG. 2A and to fill in the via hole 19a is formed. A material that is caused to generate an acid substance by irradiation with energy lines and/or heating is used for the burying material 21a. For example, a known chemically amplified resist material may be used as the burying material 21a, such as a chemically amplified resist material including polyvinyl pyrrolidone resin as a base resin, a melamine compound as a crosslinker, and an onium salt as an acid generator. The chemically amplified resist material used for the burying material 21a may be either positive or negative.

Further, in the process of FIG. 2B, the burying material 21a is irradiated with energy lines. The wavelength and exposure of the energy lines are so set as to cause generation of an acid substance from the burying material 21a. If the burying material 21a is a chemically amplified resist material, the wavelength and exposure of the exposure light may be the same as the conditions usually used for the chemically amplified resist material. That is, if the chemically amplified resist material uses the far ultraviolet light of KrF light with a wavelength of 248 nm as exposure light, KrF light is emitted as energy lines. Its exposure is, for example, 700 J/m². With respect to the range of irradiation of energy lines, either the entire burying material 21a or only the area in which the via hole 19a is formed may be irradiated.

Further, in the process of FIG. 2B, the entire structure shown in FIG. 2B is heated. As a result, a basic substance retained in the first and second interlayer insulating films 13 and 15 is diffused and penetrates through the first and second interlayer insulating films 13 and 15 toward the via hole 19a so as to reach the burying material 21a. On the other hand, as a result of the irradiation of energy lines, an acid substance is generated in the burying material 21a. Therefore, the basic substance that has penetrated into the burying material 21a is neutralized by the acid substance. The heating temperature and the heating period in this process are suitably selected. For example, the heating temperature and the heating period may be 130° C. and 90 seconds. This heating process is not necessary if the structure shown in FIG. 2B is heated sufficiently by the previous irradiation of energy lines. Further, the irradiation of energy lines and the heating may be performed simultaneously.

Next, in the process of FIG. 2C, the burying material 21a on the hard mask layer 18 is removed by dry etching. It is preferable that the surface of a burying material 21 in the via hole 19a be higher than the surface of the second interlayer insulating film 15 and lower than the surface of the hard mask layer 18. This makes it possible to prevent even slight etching of the sidewall of the second interlayer insulating film 15. As a result, it is possible to prevent the via hole 19a from expanding laterally, so that it is possible to form a finer vertical interconnection.

Next, in the process of FIG. 2D, a protection film 22 to cover the surface of the structure shown in FIG. 2C is formed. As the protection film 22, an organic material or inorganic material resistant to development liquid for developing a resist film 23 used in the next process (FIG. 2E) is used. This prevents the burying material 21 from being dissolved by the development liquid used in the process of developing the resist film 23.

Further, as the protection film 22, for example, an antireflection film of a SiN film formed with a plasma CVD apparatus using a mixture of SiH₄ gas, NH₃ gas, and N₂ gas is used. By suitably selecting the flow rate of each gas and heating temperature, it is possible to prevent reflection of exposure light from the underlayer at the time of exposing the resist film 23, so that finer patterning is performable. The protection film 22 further flattens the surface of the burying material 21, so that it is possible to further flatten the surface of the resist film 23.

The protection film 22 may be a layered body of a resin material film and an inorganic material film stacked in this order. The resin material film is, for example, a resist film of a type other than the chemically amplified type. The inorganic material film is, for example, a silicon oxide film or a spin-on-glass (SOG) film. As a result of this, the same effect as that of the above-described antireflection film is produced.

Further, in the process of FIG. 2D, a chemically amplified resist material is applied on the surface of the protection film 22, thereby forming the resist film 23. A known material may be used as the chemically amplified resist material. For example, a resist material formed of a polymer using adamantyl methacrylate as a monomer with 4,4′-diazide phenylmethylene as a crosslinker may be used.

Further, in the process of FIG. 2D, the resist film 23 is exposed to ArF light or KrF light in the pattern of an interconnection trench 15a formed in the process of FIG. 2F, so that a latent image 23a thereof is formed in the resist film 23. Further, baking is performed, for example, at 130° C. for 90 seconds. At this point, conventionally, a basic substance penetrates into the resist film 23 so as to neutralize the acid substance of the area of the latent image 23a, thus causing resist poisoning. According to the first embodiment, however, the basic substance in the first and second interlayer insulating films 13 and 15 is sufficiently neutralized by the acid substance generated from the burying material 21 in the previous process of FIG. 2B. Accordingly, it is possible to prevent the resist poisoning of the resist film 23.

Next, in the process of FIG. 2E, the resist film 23 is developed using development liquid such as tetramethyl ammonium hydroxide (TMAH), so that an opening part 23b corresponding to the interconnection trench 15a (FIG. 2F) is formed in the resist film 23. At this point, since the protection film 22 is formed, the development liquid is prevented from coming into direct contact with the burying material 21. Accordingly, the burying material 21 is prevented from being dissolved.

Next, in the process of FIG. 2F, the interconnection trench 15a is formed by dry etching. Specifically, the protection film (antireflection film) 22, the hard mask layer 18, the hard mask layer 16, and the second interlayer insulating film 15 are etched using, for example, CF₄ gas and O₂ gas with the resist film 23 serving as a mask, so that the surface of the etching stopper layer 14 is exposed. At this point, part of the surface of the burying material 21 is also etched, so that the surface of the burying material 21 is approximately as high as the surface of the etching stopper layer 14.

Next, in the process of FIG. 2G, the resist film 23 and the burying material 21 are removed by ashing. Further, the cap layer 12 at the bottom of the via hole 19a, the etching stopper layer 14 at the bottom of the interconnection trench 15a, and the hard mask layer 18 are removed by dry etching. As a result, the surface of the interconnection layer 11 is exposed.

Next, in the process of FIG. 2H, a barrier metal layer of, for example, a Ta film (not graphically illustrated) and a seed metal layer of, for example, a Cu film (not graphically illustrated) are successively formed on the side and bottom surfaces of the via hole 19a and the interconnection trench 15a by sputtering. Further, a Cu film (or CuAl film) 25 is provided by plating so as to fill in the via hole 19a and the interconnection trench 15a and to cover the structure of FIG. 2G. Further, the surface of the Cu film 25 is polished by CMP, and the polishing is stopped at the surface of the hard mask layer 16 having a lower polishing rate than the Cu film 25. The hard mask layer 16 may be removed by the polishing as shown in FIG. 2H, or the hard mask layer 16 may remain. Thereby, an interconnection structure 10 by the dual damascene process is formed.

According to the first embodiment, the burying material 21 generates an acid substance so as to neutralize the basic substance occluded in the low-k films. Accordingly, the basic substance is prevented from affecting the acid substance of the resist film 23 for forming the pattern of the interconnection trench 15a. Accordingly, it is possible to prevent occurrence of resist poisoning, thus making it possible to form a minute interconnection structure.

In the above-described first embodiment, each of the first and second interlayer insulating films 13 and 15 is formed of a low-k material. Alternatively, however, one of the first and second interlayer insulating films 13 and 15 may be formed of a low-k material, and the other may be formed of an insulating film material other than the low-k material, such as a TEOS film.

Next, a description is given of an example according to the first embodiment.

In this example, as a material for the burying material (21a or 21) of the first embodiment, a negative resist material formed of PVP resin as a base resin, a melamine compound as a crosslinker, and an onium salt as an acid generator was used. In this negative resist material, the acid generator is caused to generate an acid substance by irradiation of KrF rays.

On the other hand, in a comparative example, novolac resin was used as a material for the burying material of the first embodiment. Irradiation of light or heating does not cause this material (novolac resin) to generate an acid substance. Further, the comparative example was formed by the same process as the example except that a different burying material was employed.

Using the burying materials of the above-described example and comparative example, irradiation of KrF rays was performed with an exposure of 700 J/m², and then heating was performed at 130° C. for 90 seconds in the above-described process of FIG. 2B.

Further, in each of the example and the comparative example, in the above-described structure shown in FIG. 2C, an interconnection pattern of approximately 140 nm in width was formed in the resist film 23. The via hole 19a was 140 nm in diameter.

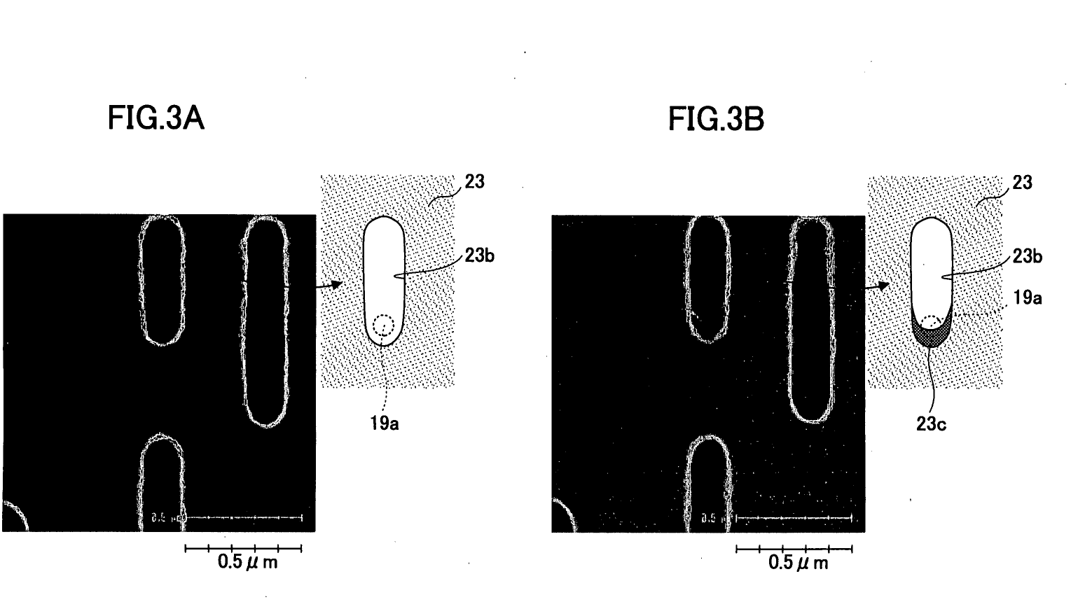

FIGS. 3A and 3B show the photographs of the resist films 23 of the example and the comparative example, respectively, after the development process. For convenience of description, a sketch of part of the opening parts 23b of the resist film 23 is shown in each of FIGS. 3A and 3B. Each of the photographs of FIGS. 3A and 3B corresponds to a plan view of the structure shown in FIG. 2E.

In the comparative example shown in FIG. 3B, a resist film 23c remains in a part of the opening part 23b, so that resist poisoning occurs. On the other hand, in the example shown in FIG. 3A, a desired pattern is formed. These show that in the example, resist poisoning is prevented from occurring, and a finer pattern can be formed in the resist film 23 than in the comparative example.

### Second Embodiment

A method of manufacturing a semiconductor device according to a second embodiment of the present invention is equal to that of the first embodiment except that a negative chemically amplified resist material is used as the burying material 21a or 21. In the drawing, the same elements as those described above are referred to by the same numerals, and a description thereof is omitted.

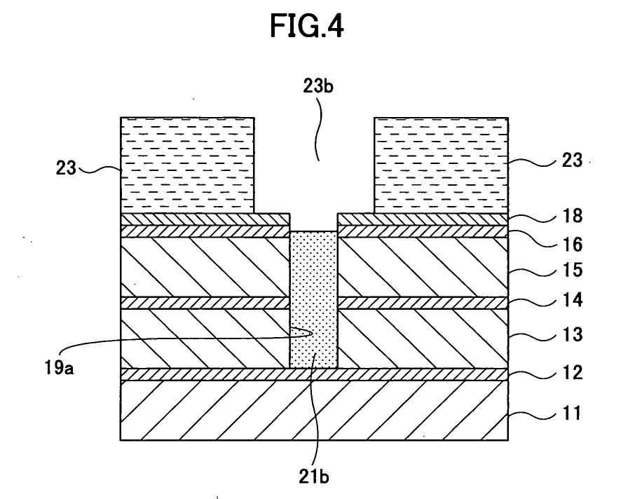

FIG. 4 is a diagram showing part of a process of manufacturing a semiconductor device according to the second embodiment.

In the process of manufacturing a semiconductor device according to the second embodiment, first, the same processes as those of FIGS. 2A through 2C of the first embodiment are performed except that a negative chemically amplified resist material is used as the burying material 21a shown in FIGS. 2B and 2C. In the case of a negative chemically amplified resist material, irradiation of exposure light causes an acid generating substance included in the chemically amplified resist material to generate an acid substance, and the acid substance acts on a dissolution inhibitor so as to convert the chemically amplified resist material into a structure insoluble in development liquid. Accordingly, in the process of FIG. 2B, a basic substance generated from the first interlayer insulating film 13 and the second interlayer insulating film 15 by exposure and heating is neutralized by the acid substance of the burying material 21a. Further, since the burying material 21a is formed of a negative chemically amplified resist material, the burying material 21a (21) has been converted into a structure insoluble in development liquid by the exposure and heating.

Next, in the process of FIG. 4, the resist film 23 is formed directly on the surface of the structure of FIG. 2C. Since a burying material 21b has been converted into a structure insoluble in development liquid, there is no need to form the protection film 22 shown in FIG. 2D. Thereafter, the processes from the resist film exposure process of FIG. 2D to the process of FIG. 2H are performed in the same manner as in the first embodiment. Thereby, an interconnection structure by the dual damascene process is formed.

According to the second embodiment, as a result of using a negative chemically amplified resist material as a material for the burying material 21b, the burying material 21b is converted into a structure insoluble in development liquid. Therefore, there is no need to provide a protection film protecting the burying material 21b from development liquid. Further, the number of processes can be less than that of the manufacturing method of the first embodiment, so that it is possible to simplify the manufacturing process. The manufacturing method according to the second embodiment produces the same effect as that of the manufacturing method of the first embodiment.

According to one aspect of the present invention, by using a material including an acid generator generating an acid substance as a burying material with which a via hole is filled, it is possible to neutralize a basic substance occluded in an interlayer insulating film of a low dielectric constant material, and to prevent the basic substance from acting on an acid substance generated by exposure of a chemically amplified resist film. As a result, it is possible to prevent occurrence of resist poisoning and thus form a fine interconnection structure.

That is, according to one aspect of the present invention, by using a material generating an acid substance as a burying material to fill in a via hole, it is possible to provide a semiconductor device manufacturing method capable of forming a fine interconnection structure by preventing occurrence of resist poisoning.

The present invention is not limited to the specifically disclosed embodiments, and variations and modifications may be made without departing from the scope of the present invention.

What is claimed is:

1. A method of manufacturing a semiconductor device, the method forming an interconnection structure by a dual damascene process, the method comprising the steps of:
(a) forming a first interlayer insulating film and a second interlayer insulating film successively over an interconnection layer, at least one of the first interlayer insulating film and the second interlayer insulating film being formed of a low dielectric constant material;
(b) forming a via hole through the first interlayer insulating film and the second interlayer insulating film;
(c) filling the via hole with a burying material formed of a material including an acid generator;
(d) causing an acid substance to be generated in the burying material;
(e) forming a chemically amplified resist film covering the second interlayer insulating film and the burying material;
(f) forming a pattern of an interconnection trench in an area including the via hole over the chemically amplified resist film;
(g) forming the interconnection trench by etching the second interlayer insulating film using the chemically amplified resist film as a mask; and
(h) filling the via hole and the interconnection trench with a conductive material.

2. The method as claimed in claim 1, wherein said step (d) irradiates the burying material with energy lines.

3. The method as claimed in claim 2, wherein:
said step (c) forms the burying material so that the burying material covers the via hole and the second interlayer insulating film; and
said step (d) irradiates an entire surface of the burying material with the energy lines.

4. The method as claimed in claim 2, wherein:
said step (c) forms the burying material so that the burying material covers the via hole and the second interlayer insulating film; and
said step (d) selectively irradiates only a part of the burying material with the energy lines, the part of the burying material covering the via hole.

5. The method as claimed in claim 1, wherein:
the burying material is formed of a chemically amplified resist material; and
said step (d) irradiates the burying material with energy lines of an exposure wavelength of the chemically amplified resist material.

6. The method as claimed in claim 5, wherein the burying material is a negative chemically amplified resist material.

7. The method as claimed in claim 1, further comprising the step of:
(i) forming a protection film resistant to development liquid of the chemically amplified resist film on a surface of the burying material between said step (d) and said step (e).

8. The method as claimed in claim 7, wherein the protection film is formed of an antireflection film.

9. The method as claimed in claim 7, wherein the burying material is formed of a positive chemically amplified resist material.

10. The method as claimed in claim 1, further comprising the step of:
(i) heating a structure formed of the first interlayer insulating film, the second interlayer insulating film, and the burying material after said step (d).

11. The method as claimed in claim 1, wherein the low dielectric constant material is selected from a group consisting of a SiOC film, a SiOF film, a SiO₂—B₂O₃ film, a porous silica film, and an organic siloxane film.

12. A method of manufacturing a semiconductor device, the method forming an interconnection structure by a dual damascene process, the method comprising the steps of:
(a) forming a cap layer, a first interlayer insulating film of a low dielectric constant material, an etching stopper layer, a second interlayer insulating film of a low dielectric constant material, and a hard mask layer successively over an interconnection layer;
(b) forming a via hole exposing a surface of the cap layer by etching the first interlayer insulating film, the etching stopper layer, the second interlayer insulating film, and the hard mask layer;
(c) forming a burying material of a material including an acid generator so that the via hole is filled and a surface of the hard mask layer is covered with the burying material;
(d) causing an acid substance to be generated in the burying material by irradiating a substantially entire surface of the burying material with energy lines;
(e) heating the burying material, the first interlayer insulating film, and the second interlayer insulating film;
(f) forming a chemically amplified resist film covering the hard mask layer and the burying material;
(g) forming a pattern of an interconnection trench in an area including the via hole over the chemically amplified resist film;
(h) forming the interconnection trench by etching the second interlayer insulating film using the chemically amplified resist film as a mask; and
(i) filling the via hole and the interconnection trench with a conductive material.
